(19) United States
(12) Patent Application Publication
(10) Pub. No.: US 2010/0090219 A1
(43) Pub. Date: Apr. 15, 2010

(54) METHOD FOR FABRICATION OF SEMICONDUCTOR DEVICE

(76) Inventor: Oh-Jin Jung, Yongn-si (KR)

Correspondence Address: SHERR & VAUGHN, PLLC, 620 HERNDON PARKWAY, SUITE 320, HERNDON, VA, 20170, US

(21) Appl. No.: 12/568,867

(22) Filed: Sep. 29, 2009

(30) Foreign Application Priority Data
Oct. 10, 2008 (KR) 10-2008-0099570

(51) Int. Cl. H01L 29/04; H01L 21/265

(52) U.S. Cl. 257/52; 438/524; 257/49; 257/774; 257/E29.003; 257/E21.334

(57) ABSTRACT

A method of fabrication of a semiconductor device having low resistance in an interconnection line and the same coefficient of thermal expansion as a semiconductor substrate is disclosed. The method includes forming a nitride film over a semiconductor substrate including a bottom metal line and a top metal line connected to each other through a plurality of vias, forming a trench at a through-silicon via (TSV) region of the semiconductor substrate, filling the trench with a predetermined material to form a silicon film, exposing the silicon film using a photoresist pattern, ion-implanting a dopant into the exposed silicon film, and selectively performing laser annealing to the silicon film to diffuse only the dopant implanted into the silicon film.

The present application claims priority under 35 U.S.C. 119 to Korean Patent Application No. 10-2008-0099570 (filed on Oct. 10, 2008), which is hereby incorporated by reference in its entirety.

### BACKGROUND

Packaging technology for integrated circuits has been developed to satisfy the demand for miniaturization and reliable mounting. Various related stack technologies have been developed to meet the demand for high performance and miniaturization of electronic products.

In the semiconductor industry, the term “stack” means that at least two chips or packages are stacked vertically. For a memory device, through the use of stack technology, it is possible to realize a product having a memory capacity twice or more that which can be realized in a semiconductor integration process. Also, in addition to the increase of a memory capacity, stack packages have an advantage in mount density and efficient use of a mounting surface. Therefore, the stack package is under accelerated research and development.

A structure using a through silicon via (TSV) has been proposed as an example of a stack package. A stack package using the TSV has a structure in which the TSV is formed in each chip. Physical and electrical connections between chips are made vertically by the TSV. The stack package is fabricated as follows.

A vertical hole is formed in a predetermined region of each chip at the wafer level, and an insulation film is formed over the surface of the vertical hole. A seed layer is formed over the insulation film, and the vertical hole is filled with an electrolyte, i.e., metal, by electroplating to form a TSV. Subsequently, the backside of the wafer is ground to expose the TSV. Then, the wafer is divided into individual chips by sawing, and at least two chips are vertically stacked on a substrate using the TSV. Subsequently, the top of the substrate, including the stacked chips, is molded, and a solder ball is mounted to the bottom of the substrate, to complete the fabrication of the stack package.

In a related stack package using such a TSV, however, the vertical hole is filled with an electrolyte, i.e., copper, to form the TSV. At this time, heat is generated, with the result that cracking occurs due to the difference in coefficient of thermal expansion between the silicon and the copper. Junction reliability is greatly deteriorated.

### SUMMARY

Embodiments relate to a method of fabrication of a semiconductor device. More particularly, embodiments relate to a method of fabrication of a semiconductor device having low resistance in an interconnection line and the same coefficient of thermal expansion as a semiconductor substrate.

Embodiments relate to a method of fabrication of a semiconductor device which includes forming a nitride film over a semiconductor substrate including a bottom metal line and a top metal line connected to each other through a plurality of vias, forming a trench at a through silicon via (TSV) region of the semiconductor substrate, filling the trench with a predetermined material to form a silicon film, exposing the silicon film using a photoresist pattern to expose the silicon film and ion-implanting a dopant into the exposed silicon film, and selectively performing laser annealing to the silicon film to diffuse only the dopant constituting the silicon film.

Embodiments also relate to an apparatus configured to form a nitride film over a semiconductor substrate comprising a bottom metal line and a top metal line connected to each other through a plurality of vias, form a trench at a through-silicon via region of the semiconductor substrate, fill the trench with a predetermined material to form a silicon film, expose the silicon film using a photoresist pattern, ion-implant a dopant into the exposed silicon film, and selectively anneal the silicon film with a laser to diffuse only the dopant implanted into the silicon film.

### DRAWINGS

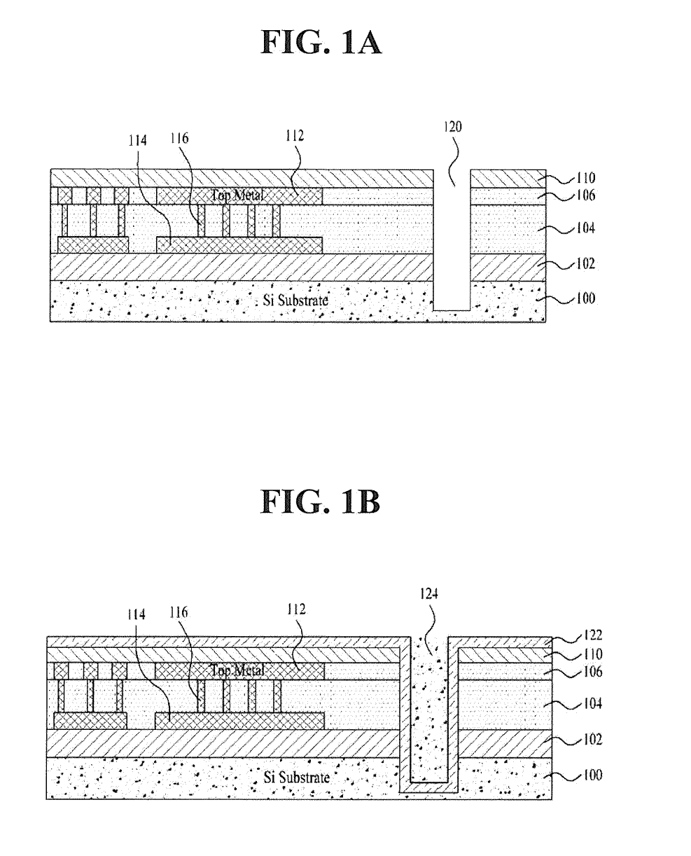

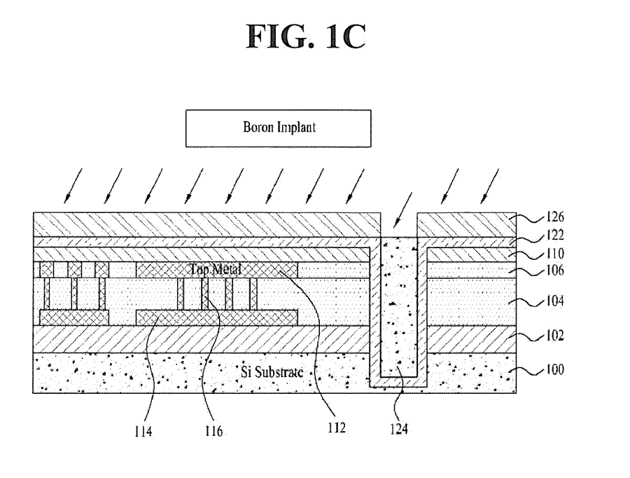

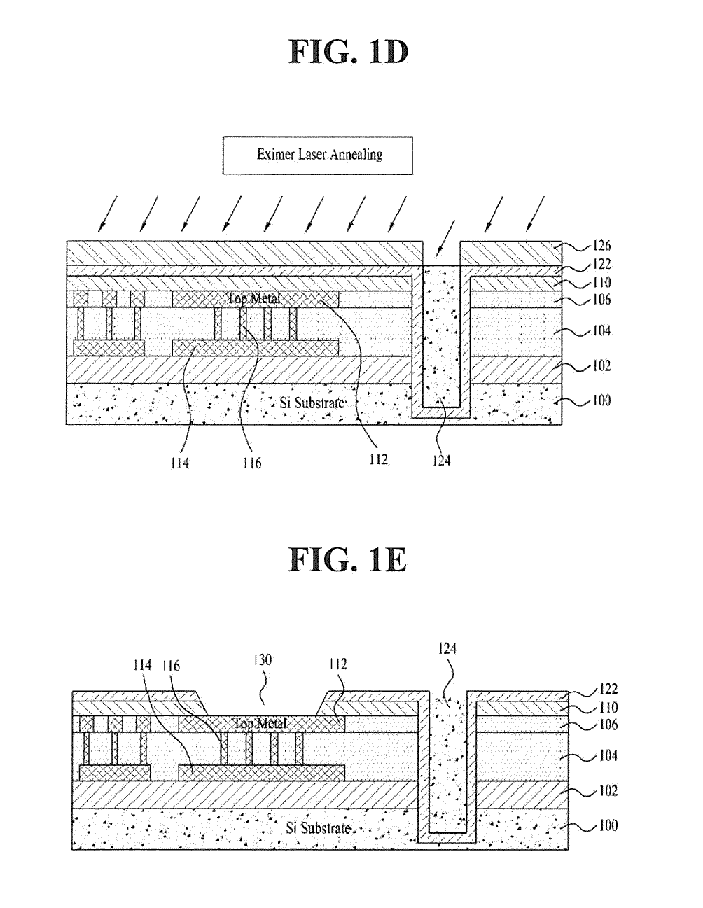

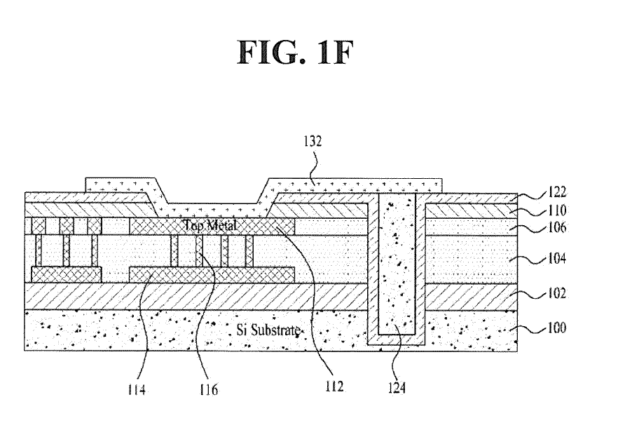

Example FIGS. 1A to 1F are views illustrating a method for fabrication of a semiconductor device according to embodiments.

### DESCRIPTION

Example FIGS. 1A to 1F are views illustrating a method for fabrication of a semiconductor device according to embodiments. Processes are shown in order. Referring first to example FIG. 1A, a nitride film (plasma-enhanced(PE)-nitride) may be formed over a semiconductor substrate 100 including a top metal line 112 and a bottom metal line 114 having through silicon via (TSV) forming regions. The top metal line 112 and the bottom metal line 114 may be connected to each other through a plurality of vias 116.

A pre-metal dielectric (PMD) layer 102 may be formed between the bottom metal line 114 and the semiconductor substrate 100. A first inter metal dielectric (IMD) layer 104 may be formed between the top metal line 112 and the bottom metal line 114. A second IMD layer 106 may be formed together with the top metal line 112 over the first IMD layer 104. In other words, as shown in FIG. 1A, the second IMD layer 106 is formed in the same layer as the top metal line 112, over the first IMD layer 104.

Subsequently, a photoresist may be applied, and a first photoresist pattern to expose the TSV forming regions may be formed by exposure and development. The exposed TSV forming regions are etched, using the first photoresist pattern as an etching mask, to form a trench 120. The deep trench 120 may be formed to a predetermined depth in the semiconductor substrate 100 through the PMD layer 102, the first IMD layer 104, the second IMD layer 106, and the nitride film 110.

Subsequently, as shown in example FIG. 1B, the first photoresist pattern used as the etching mask may be removed by etching. An insulation film 122 may be formed over the entire surface of the nitride film 110, including the surface of the trench 120, to prevent diffusion of an electrolyte. The insulation film 122 may be formed of a nitride film or an oxide film by high-temperature dry etching or wet etching.

Subsequently, poly silicon or amorphous silicon (A-Si) may be deposited over the entire surface of the nitride film 110, including the insulation film 122 and the trench 120, by plasma enhanced chemical vapor deposition (PECVD) to fill the trench 120. The deposited poly silicon or A-Si may be flattened by chemical mechanical polishing (CMP), such that the insulation film 122 is exposed, to form a silicon film 124.

Subsequently, as shown in example FIG. 1C, a photoresist may be applied to the entire surface thereof, and a second photoresist pattern 126, designed to expose a region of the silicon film 124 corresponding to the TSV forming regions, may be formed by exposure and development. A dopant may be ion-implanted into the exposed silicon film 124 using the second photoresist pattern 126 as an ion implant mask. A group 3 element such as boron or a group 5 element may be used as the dopant, and the ion implantation may be performed with an energy of 11 B+15 to 350 KeV.

Subsequently, as shown in example FIG. 1D, laser annealing, such as eximer laser annealing, is performed for activation of the silicon film 124 to selectively diffuse only the dopant constituting the silicon film 124. The laser annealing may be performed at a wavelength of 1,000 to 1,500 nm and with an energy density of 2 J/cm² to 10 J/cm².

Since, unlike a related rapid thermal process (RTP), only the silicon film 124 is selectively annealed by the laser annealing, the metal lines and the oxide film do not substantially deteriorate. As a result, the resistance of the bottom metal line 114 and the top metal line 112 is lowered, and, at the same time, the coefficient of thermal expansion (CTE) as a general TSV is achieved.

As shown in example FIG. 1E, the portions of the nitride film 110 and the insulation film 122 corresponding to the top metal line 112 are selectively etched to form a pad opening 130 through which the top metal line 112 is partially exposed. As shown in example FIG. 1F, the pad opening 130 is filled with metal, and the remaining photoresist is removed to form a redistribution layer 132 to interconnect the silicon film 124 and a bump pad. Known subsequent processes may be performed to complete a semiconductor device.

As apparent from the above description, the method of fabrication of the semiconductor device according to embodiments selectively diffuses only the dopant constituting the TSV silicon through the laser annealing, thereby lowering resistance of the interconnection line and providing the same coefficient of thermal expansion as the semiconductor substrate and the poly silicon TSV.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a nitride film over a semiconductor substrate comprising a bottom metal line and a top metal line connected to each other through a plurality of vias;
forming a trench at a through-silicon via region of the semiconductor substrate;
filling the trench with a predetermined material to form a silicon film;
exposing the silicon film using a photoresist pattern;
ion-implanting a dopant into the exposed silicon film; and
selectively performing laser annealing to the silicon film to diffuse only the dopant implanted into the silicon film.

2. The method of claim 1, including:
selectively etching portions of a nitride film and an insulation film corresponding to the top metal line to form a pad opening through which the top metal line is partially exposed; and
filling the pad opening with metal to form a redistribution layer.

3. The method of claim 1, wherein the semiconductor substrate includes:
a pre-metal dielectric layer formed between the bottom metal line and the semiconductor substrate;
a first inter-metal dielectric layer formed between the top metal line and the bottom metal line; and
a second inter-metal dielectric layer formed in the same layer with the top metal line, over the first inter-metal dielectric layer.

4. The method of claim 1, including forming an insulation film over a surface of the trench after forming the trench.

5. The method of claim 4, wherein the insulation film is formed of an oxide film.

6. The method of claim 4, wherein the insulation film is formed of a nitride film.

7. The method of claim 1, wherein the silicon film is formed by depositing poly silicon.

8. The method of claim 7, including flattening the deposited poly silicon by chemical mechanical polishing.

9. The method of claim 1, wherein the silicon film is formed by plasma enhanced chemical vapor deposition.

10. The method of claim 1, wherein the silicon film is formed by depositing amorphous silicon by plasma enhanced chemical vapor deposition and flattening the deposited amorphous silicon by chemical mechanical polishing.

11. The method of claim 1, wherein the step of ion-implanting the dopant is performed with a group 3 element.

12. The method of claim 1, wherein the step of ion-implanting the dopant is performed with a group 5 element.

13. The method of claim 1, wherein the ion-implanting the dopant is performed with boron (B).

14. The method of claim 1, wherein the laser annealing is performed at a wavelength of 1,000 to 1,500 nm.

15. The method of claim 1, wherein the laser annealing is performed with an energy density of 2 J/cm² to 10 J/cm².

16. The method of claim 3, wherein the trench is formed through the pre-metal dielectric layer, the first inter-metal dielectric layer, the second inter-metal dielectric layer, and the nitride film.

17. An apparatus configured to:
form a nitride film over a semiconductor substrate comprising a bottom metal line and a top metal line connected to each other through a plurality of vias;
form a trench at a through-silicon via region of the semiconductor substrate;
fill the trench with a predetermined material to form a silicon film;
expose the silicon film using a photoresist pattern;
ion-implant a dopant into the exposed silicon film; and
selectively anneal the silicon film with a laser to diffuse only the dopant implanted into the silicon film.

18. The apparatus of claim 17, wherein the semiconductor substrate includes:
a pre-metal dielectric layer formed between the bottom metal line and the semiconductor substrate;
a first inter-metal dielectric layer formed between the top metal line and the bottom metal line; and
a second inter-metal dielectric layer formed in the same layer with the top metal line, over the first inter-metal dielectric layer, wherein the apparatus is configured to form the trench through the pre-metal dielectric layer, the first inter-metal dielectric layer, the second inter-metal dielectric layer, and the nitride film.

19. The apparatus of claim 17, configured to form the silicon film by depositing amorphous silicon by plasma enhanced chemical vapor deposition and flattening the deposited amorphous silicon by chemical mechanical polishing.

20. The apparatus of claim 17, configured to form the silicon film by depositing poly silicon by plasma enhanced chemical vapor deposition and flattening the deposited poly silicon by chemical mechanical polishing.
